(19) United States
(12) Patent Application Publication
(10) Pub. No.: US 2019/0378742 A1
(43) Pub. Date: Dec. 12, 2019

(54) CARRIER FOR USE IN A VACUUM SYSTEM, SYSTEM FOR VACUUM PROCESSING, AND METHOD FOR VACUUM PROCESSING OF A SUBSTRATE

(71) Applicant: Applied Materials, Inc., Santa Clara, CA (US)

(72) Inventors: Tommaso VERCESI, Aschaffenburg (DE); Michael Rainer SCHULTHEIS, Rödermark (DE)

(21) Appl. No.: 15/744,021

(22) PCT Filed: Feb. 24, 2017
(86) PCT No.: PCT/EP2017/054354

§ 371 Date: Jan. 11, 2018

(51) Int. Cl. H01L 21/683; C23C 14/12; H01L 21/67; C23C 14/56; C23C 14/04

(52) U.S. Cl. CPC H01L 21/6833; C23C 14/12; C23C 14/042; C23C 14/56; H01L 21/67253

(57) ABSTRACT

The present disclosure provides a carrier (100) for use in a vacuum system (300). The carrier (100) includes a housing (120) configured to accommodate one or more electronic devices (130) and contain a gaseous environment during the use of the carrier (100) in the vacuum system (300), wherein the carrier (100) is configured to hold at least one of a substrate (10) and a mask (20) used during vacuum processing.

### FIELD

Embodiments of the present disclosure relate to a carrier for use in a vacuum system, a system for vacuum processing, and a method for vacuum processing of a substrate. Embodiments of the present disclosure particularly relate to an electrostatic chuck (E-chuck) for holding substrates and/or masks used in the manufacture of organic light-emitting diode (OLED) devices.

### BACKGROUND

Techniques for layer deposition on a substrate include, for example, thermal evaporation, physical vapor deposition (PVD), and chemical vapor deposition (CVD). Coated substrates may be used in several applications and in several technical fields. For instance, coated substrates may be used in the field of organic light emitting diode (OLED) devices. OLEDs can be used in the manufacture of television screens, computer monitors, mobile phones, other hand-held devices, and the like for displaying information. An OLED device, such as an OLED display, may include one or more layers of an organic material situated between two electrodes that are all deposited on a substrate.

During vacuum processing, the substrate can be supported by a carrier configured to hold the substrate and an optional mask. For applications such as organic light emitting devices, a purity and uniformity of the organic layers deposited on the substrate should be high. Further, there has been a continuous increase in substrate sizes. The increasing size of substrates makes the handling and transportation of the carriers supporting substrates and masks, e.g. without sacrificing the throughput by substrate breakage, increasingly challenging. Moreover, the space available for a carrier inside a vacuum chamber can be limited. Accordingly, there is also a need to reduce the space used by carriers inside a vacuum chamber.

In view of the above, new carriers for use in a vacuum system, systems for vacuum processing, and methods for vacuum processing of a substrate that overcome at least some of the problems in the art are beneficial. The present disclosure particularly aims at providing carriers that can be efficiently transported in a vacuum chamber.

### SUMMARY

In light of the above, a carrier for use in a vacuum system, a system for vacuum processing, and a method for vacuum processing of a substrate are provided. Further aspects, benefits, and features of the present disclosure are apparent from the claims, the description, and the accompanying drawings.

According to an aspect of the present disclosure, a carrier for use in a vacuum system is provided. The carrier includes a housing configured to accommodate one or more electronic devices and contain a gaseous environment during the use of the carrier in the vacuum system, wherein the carrier is configured to hold at least one of a substrate and a mask used during vacuum processing.

According to a further aspect a carrier for use in a vacuum system is provided. The carrier includes a support structure having a receiving surface for a mask or a substrate thereon and a sealable recess therein to accommodate one or more electronic devices.

According to a further aspect a carrier for use in a vacuum system is provided. The carrier includes a support structure having a receiving surface for a mask or a substrate thereon and a sealable recess therein to accommodate one or more electronic devices selected from the group consisting of a first control device for controlling a movement of the carrier, a second control device for controlling one or more operation parameters of the carrier, an alignment control device, a wireless transmitting device, a pressure sensor, and a power source.

According to another aspect of the present disclosure, a system for vacuum processing is provided. The system includes a vacuum chamber, the carrier according to the embodiments described herein, and a transport arrangement configured for transportation of the carrier in the vacuum chamber.

According to yet another aspect of the present disclosure, a system for vacuum processing is provided. The system includes two or more processing regions and a transport arrangement configured for sequentially transporting a carrier supporting a substrate thereon to, or through, the two or more processing regions.

According to a further aspect of the present disclosure, a method for vacuum processing of a substrate is provided. The method includes supporting at least one of the substrate and a mask on a carrier in a vacuum chamber, wherein the carrier includes a housing accommodating one or more electronic devices, and containing a gaseous environment inside the housing during the vacuum processing of the substrate in the vacuum chamber.

According to a further aspect a method for vacuum processing of a substrate is provided. The method includes supporting at least one of the substrate and a mask on a carrier in a vacuum chamber, wherein the carrier includes a sealable recess accommodating one or more electronic devices, and maintaining a gaseous environment inside the sealable recess during the vacuum processing of the substrate in the vacuum chamber.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1A shows a schematic view of a carrier for use in a vacuum system according to embodiments described herein;

FIGS. 1B and C show cross-sectional views of the carrier of FIG. 1A according to embodiments described herein;

FIG. 2 shows a schematic view of a carrier for use in a vacuum system according to further embodiments described herein;

FIG. 3 shows a schematic view of a system for vacuum processing according to embodiments described herein;

FIGS. 4A and B show schematic views of a transport arrangement for transporting a carrier in a vacuum chamber according to embodiments described herein;

FIG. 5 shows a schematic view of a system for vacuum processing according to further embodiments described herein; and

FIG. 6 shows a flow chart of a method for vacuum processing of a substrate according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Carriers can be used in a vacuum system, such as a vacuum deposition system, for holding and transporting substrates and/or masks within a vacuum chamber of the vacuum system. As an example, one or more material layers can be deposited on the substrate while the substrate is supported by the carrier. For applications such as organic light emitting devices a high purity and uniformity of the organic layers deposited on the substrate can be beneficial.

The carrier of the present disclosure has a housing accommodating one or more electronic devices, such as control devices used for controlling an operation and/or a movement of the carrier. The housing can be an enclosure or a recess surrounding a space. The housing, enclosure or recess can be sealable. According to some embodiments, the housing or space contains a gaseous environment even if the carrier is located inside the vacuum chamber, i.e., in a vacuum environment. The carrier of the present disclosure can be an autonomous entity that is not mechanically connected e.g. via wires or cables to the surroundings of the carrier. An improved purity and uniformity of the layers deposited on the substrate can be achieved, since particle generation during a movement of the carrier is minimized. Further, the vacuum inside the vacuum chamber is not compromised because the housing or recess, i.e. an enclosure, having the gaseous environment is sealed. Moreover, the vacuum inside the vacuum chamber can even be improved because there is no need to establish vacuum conditions in a challenging region, i.e., the region having the one or more electronic components. Further, by keeping the housing or recess vacuum-tightly closed, an outgassing of the one or more electronic devices does not affect the vacuum environment inside the vacuum chamber.

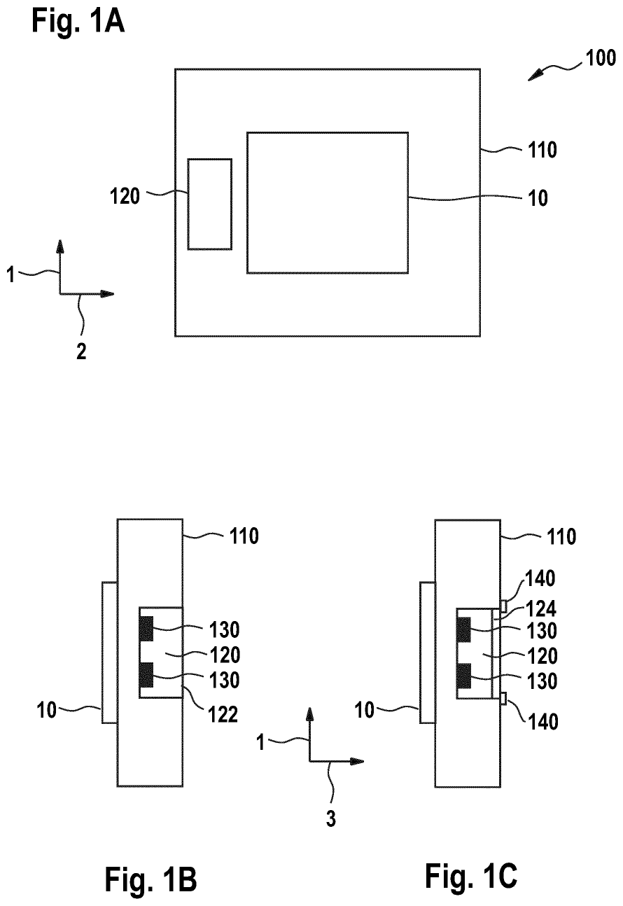

FIG. 1A shows a schematic view of a carrier 100 for use in a vacuum system according to embodiments described herein. FIGS. 1B and C show cross-sectional views of the carrier 100 of FIG. 1A.

The carrier 100 is configured to hold a substrate 10 and/or a mask (not shown) used during vacuum processing. In some implementations, the carrier 100 can be configured to support both the substrate 10 and the mask. In further implementations, the carrier 100 can be configured to support either the substrate 10 or the mask. In such a case, the carrier 100 can be referred to as “substrate carrier” and “mask carrier”, respectively.

The carrier 100 can include a support structure or body 110 providing a support surface, which can be an essentially flat surface configured for contacting e.g. a back surface of the substrate 10. In particular, the substrate 10 can have a front surface (also referred to as “processing surface”) opposite the back surface and on which a layer is deposited during the vacuum processing, such as a vacuum deposition process.

The carrier 100 includes a housing 120 or recess (i.e. an enclosure of a space) configured to accommodate one or more electronic devices 130. The housing or recess is sealed, e.g. to contain (or maintain or keep) a gaseous environment inside the housing 120 during the use of the carrier 100 in the vacuum system. In other words, the housing 120 or recess contains gas sealed inside housing 120 such that the gas does not leak into a vacuum chamber of the vacuum system. The housing 120 can enclose or define a space in which the gaseous environment is contained. According to some embodiments, the gaseous environment can contain a gas selected from the group consisting of atmosphere, nitrogen, helium, and any combination thereof. As an example, helium can be used such that a leak detector connected to the vacuum chamber of the vacuum system can detect whether there is a leak at the carrier 100.

The term “vacuum” as used throughout the present disclosure can be understood in the sense of a technical vacuum having a vacuum pressure of less than, for example, 10 mbar. The pressure in the vacuum chamber may be between 10⁻⁵ mbar and about 10⁻⁸ mbar, specifically between 10⁻⁵ mbar and 10⁻⁷ mbar, and more specifically between about 10⁻⁶ mbar and about 10⁻⁷ mbar. One or more vacuum pumps, such as turbo pumps and/or cryo-pumps, connected to the vacuum chamber for generation of the vacuum inside the vacuum chamber can be provided.

According to some embodiments, a gas pressure of the gaseous environment, i.e., the pressure inside the housing 120, is at least twice the pressure in the vacuum chamber.

As an example, the gas pressure of the gaseous environment is 10⁻⁷ mbar or more, specifically 10⁻⁵ mbar or more, specifically 10⁻³ mbar or more, specifically 1 mbar or more, specifically 10 mbar or more, and more specifically 100 mbar or more. In some implementations, the gas pressure of the gaseous environment is approximately ambient pressure, i.e., approximately 1 bar at 15° C. It is to be understood that the gas pressure inside the housing can vary over time, e.g. due to elevated temperatures during a layer deposition process.

According to some embodiments, the housing 120 or enclosure can be provided by a recess in the body 110 of the carrier 100. In other embodiments, the housing 120 can be provided as a separate element, such as a box, that is attached to (or mounted on) the carrier 100. The housing 120 can be referred to as “atmosphere box” or “atmospheric box”. In some implementations, the housing 120, and particularly the space enclosed by the housing 120, can have a volume of 1 cm³ or more, specifically 10 cm³ or more, specifically 50 cm³ or more, specifically 100 cm³ or more, and more specifically 200 cm³ or more.

The carrier 100 can be configured for transportation through the vacuum chamber, and in particular through a deposition area, along a transportation path, such as a linear transportation path. In some implementations, the carrier 100 is configured for transportation in a transport direction 2, which can be a horizontal direction. According to some embodiments, which can be combined with other embodiments described herein, the carrier 100 is configured for contactless levitation and/or contactless transportation in the vacuum system. As an example, the carrier 100 can be transported in the vacuum system, and particularly in the vacuum chamber, using a transport arrangement. The transport arrangement can be configured for contactless levitation of the carrier and/or contactless transportation of the carrier in the vacuum chamber.

According to some embodiments, which can be combined with other embodiments described herein, the carrier 100 is configured for holding or supporting the substrate and/or mask in a substantially vertical orientation. As used throughout the present disclosure, “substantially vertical” is understood particularly when referring to the substrate orientation to allow for a deviation from the vertical direction or orientation of ±20° or below, e.g. of ±10° or below. This deviation can be provided for example because a substrate support with some deviation from the vertical orientation might result in a more stable substrate position. Further, fewer particles reach the substrate surface when the substrate is tilted forward. Yet, the substrate orientation, e.g., during the vacuum deposition process, is considered substantially vertical, which is considered different from the horizontal substrate orientation, which may be considered as horizontal ±20° or below.

The term “vertical direction” or “vertical orientation” is understood to distinguish over “horizontal direction” or “horizontal orientation”. That is, the “vertical direction” or “vertical orientation” relates to a substantially vertical orientation e.g. of the carrier and the substrate 10, wherein a deviation of a few degrees, e.g. up to 10° or even up to 15°, from an exact vertical direction or vertical orientation is still considered as a “substantially vertical direction” or a “substantially vertical orientation”. The vertical direction can be substantially parallel to the force of gravity.

Turning now to FIGS. 1B and C, the housing 120 is shown in an open state and a closed state, respectively. In particular, the housing 120 can be openable e.g. for maintenance and/or replacement of the one or more electronic devices 130. The housing 120 can be opened when the carrier 100 is outside the vacuum system, e.g., for maintenance or repair. The housing 120 can be closable to seal the gas inside the housing 120.

According to some embodiments, the carrier 100, and particularly the housing 120, includes one or more openings 122. The one or more openings 122 can be configured to provide access to the housing 120, and particularly to the one or more electronic devices 130 provided therein. The one or more openings 122 can be provided at the same side or surface of the carrier 100 having the substrate 10 and/or mask positioned thereon, e.g., a front side. However, the one or more openings 122 can be provided at other locations of the carrier 100, e.g., at a back side of the carrier 100 opposite the front side, as it is illustrated in FIGS. 1B and C.

In some implementations, the carrier 100 includes a closure element 124 configured to seal the housing 120 for keeping or maintaining the gaseous environment inside the housing 120. As an example, the closure element 124 can be configured to seal the housing essentially vacuum-tight. In some embodiments, the closure element 124 can be configured to seal the one or more openings 122. As an example, one opening and one closure element configured to seal the one opening can be provided. In another example, multiple openings and multiple closure elements can be provided, wherein each closure element of the multiple closure elements can be configured to seal a respective opening of the multiple openings.

In some implementations, the closure element 124 includes, or is, a lid or plate configured to cover the housing 120, and particularly the one or more openings 122. As an example, the housing 120 or enclosure can be provided as a recess in the body 110 of the carrier 100. The closure element 124 can be configured to cover the recess, e.g., by inserting the closure element 124 into the recess or placing the closure element 124 over the recess. In another example, the housing 120 can be provided by a separate element, such as a box, that is attached to (or mounted on) the carrier 100, and particularly the body 110. The closure element 124 can be a lid for closing the box.

According to some embodiments, the carrier 100 can include a fastening arrangement 140 configured for fastening the closure element 124 to the carrier 100 to seal the housing 120 or enclosure. As an example, the fastening arrangement 140 can be configured to immovably attach the closure element 124 to the carrier 100, and particularly to the body 110. The fastening arrangement 140 can include one or more fastening devices selected from the group consisting of mechanical fastening devices, electric fastening devices, magnetic fastening devices, and electromagnetic fastening devices. The mechanical first devices can include at least one of clamps, screws and bolts to mechanically fix the closure element 124. The electric fastening devices can include an electric locking device. The magnetic fastening devices and the electromagnetic fastening devices can include magnets, such as permanent magnets and/or electromagnets, to fix the closure element using a magnetic force or an electromagnetic force.

According to some embodiments, one or more sealing devices can be provided at the closure element 124 to seal the housing 120 or enclosure, e.g. a recess. As an example, the one or more sealing devices can be arranged between the closure element 124 and the body 110. The one or more sealing devices can for instance be O-rings or a copper sealing. The one or more sealing devices can be configured to seal the housing 120 substantially air-tight or vacuum tight. Herein, reference is made to a housing. The housing can be an enclosure or a recess, which can be sealed.

According to some embodiments, which can be combined with other embodiments described herein, the carrier 100 includes one or more alignment devices. The one or more alignment devices can be configured for aligning a relative position between the substrate 10 and the mask. As an example, the one or more alignment devices can be electric or pneumatic actuators. The one or more alignment devices can for example be linear alignment actuators. In some implementations, the one or more alignment devices can include at least one actuator selected from the group consisting of: a stepper actuator, a brushless actuator, a DC (direct current) actuator, a voice coil actuator, and a piezoelectric actuator. The term “actuator” can refer to motors, e.g., stepper motors.

The one or more alignment devices can be configured to move or position the substrate and the mask with respect to each other with a precision of less than about plus/minus 1 micrometer. As an example, the one or more alignment devices can be configured to move or position the mask or a mask support supporting the mask. Optionally or alternatively, the one or more alignment devices can be configured to move or position the substrate or a substrate support supporting the substrate. The carrier of the present disclosure can include the mask support and/or the substrate support. A precision of the alignment can be about plus/minus 0.5 micrometer, and specifically about 0.1 micrometer, in at least one of the z-direction (e.g. the vertical direction 1), the x-direction (e.g., the transport direction direction 2), and the y-direction (direction 3).

According to some embodiments, which can be combined with other embodiments described herein, the one or more electronic devices 130 can be selected from the group including a first control device for controlling a movement of the carrier 100, a second control device for controlling one or more operation parameters of the carrier 100, an alignment control device, a wireless communication device, a pressure sensor, and a power source. For example, the power source can be a battery or battery system.

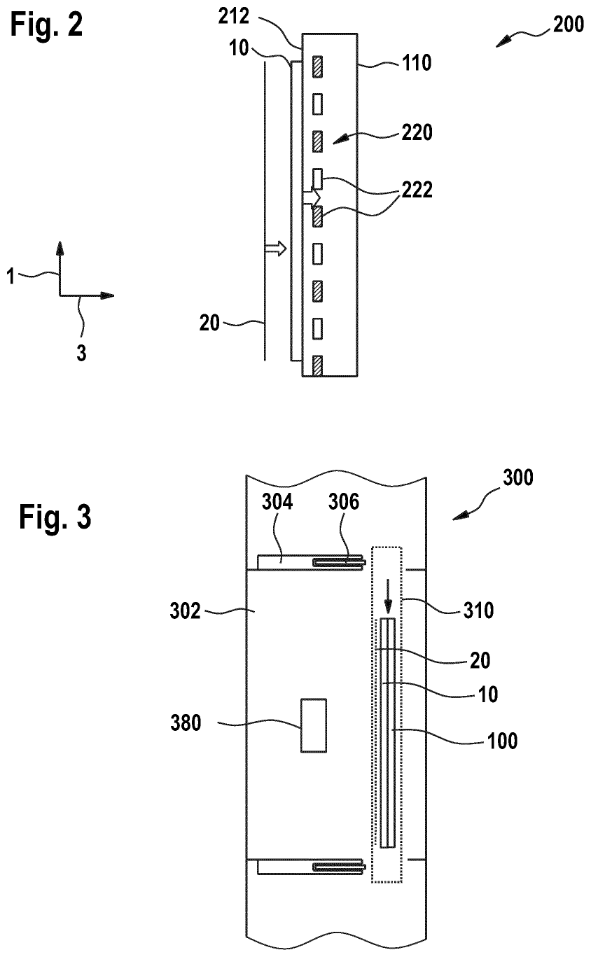

The first control device for controlling a movement of the carrier 100 can be configured to control the movement of the carrier 100 through the vacuum chamber, and in particular through a deposition area along the transportation path, such as the linear transportation path. The second control device can be configured to control a holding action of the substrate and/or the mask. As an example, the one or more operation parameters can include, but are not limited to, a force acting on the substrate 10 and/or the mask to hold the substrate 10 and the mask at the carrier 100. Specifically, the carrier can be an electrostatic chuck, wherein the one or more operation parameters are operation parameters of the electrostatic chuck. The operation of the electrostatic chuck is further explained with respect to FIG. 2. The carrier can be considered a “smart carrier”. The one or more electronic device can be configured to e.g. measure leakage current of the S-chuck, to measure failure of the battery, and/or to measure failure of de-chucking of the substrate, e.g. a glass substrate. The alignment control device can be configured to control an alignment process of at least one of the carrier 100, the substrate 10, and the mask. As an example, the alignment control device can be configured to control the one or more alignment devices for aligning the substrate 10 and the mask with respect to each other. Optionally or alternatively, the alignment control device can be configured to align an orientation of the carrier 100 in the vacuum chamber.

The pressure sensor can be configured to measure a gas pressure inside the housing 120, particularly during the use of the carrier 100 in the vacuum system. The pressure sensor can measure the gas pressure continuously or in predetermined time intervals. The measured gas pressure can be transmitted to a monitoring device remote from the carrier 100. As an example, if the pressure sensor determines a pressure drop in the housing 120 while the carrier 100 is in the vacuum environment provided by the vacuum chamber, it can be concluded that gas from the housing 120 leaks into the vacuum environment, such that proper measures can be taken.

The wireless communication device can be configured to provide a wireless communication between the one or more electronic devices 130 of the autonomous carrier and the surroundings of the carrier 100. No wired connection needs to be provided and a particle generation inside the vacuum chamber e.g. due to a carrier movement can be reduced or even avoided. As an example, the wireless communication device can include a wireless transmitter configured to transmit the gas pressure measured by the pressure sensor to the monitoring device. Optionally or alternatively, the wireless communication device can include a wireless receiver configured to receive data, such as control commands, for controlling e.g. the movement, alignment processes, and/or the operation parameters of the carrier 100.

The power source included in the housing 120 can be a power source for the one or more electronic devices 130. In some implementations, the power source can be a power source of the electrostatic chuck that is used to generate the holding force for attracting the substrate 10 and/or the mask. Optionally or alternatively, the power source can provide power for operating the pressure sensor and/or the wireless communication device. As an example, the power source can be a battery or battery system.

The embodiments described herein can be utilized for evaporation on large area substrates, e.g., for OLED display manufacturing. Specifically, the substrates for which the structures and methods according to embodiments described herein are provided are large area substrates. For instance, a large area substrate or carrier can be GEN 4.5, which corresponds to a surface area of about 0.67 m² (0.73×0.92m), GEN 5, which corresponds to a surface area of about 1.4 m² (1.1 m×1.3 m), GEN 7.5, which corresponds to a surface area of about 4.29 m² (1.95 m×2.2 m), GEN 8.5, which corresponds to a surface area of 10 about 5.7 m² (2.2 m×2.5 m), or even GEN 10, which corresponds to a surface area of about 8.7 m² (2.85 m×3.05 m). Even larger generations such as GEN 11 and GEN 12 and corresponding surface areas can similarly be implemented. Half sizes of the GEN generations may also be provided in OLED display manufacturing.

According to some embodiments, which can be combined with other embodiments described herein, the substrate thickness can be from 0.1 to 1.8 mm. The substrate thickness can be about 0.9 mm or below, such as 0.5 mm. The term “substrate” as used herein may particularly embrace substantially inflexible substrates, e.g., a wafer, slices of transparent crystal such as sapphire or the like, or a glass plate. However, the present disclosure is not limited thereto and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or below, such as 0.5 mm or below, wherein the flexibility of the substantially inflexible substrate is small in comparison to the flexible substrates.

According to embodiments described herein, the substrate may be made of any material suitable for material deposition. For instance, the substrate may be made of a material selected from the group consisting of glass (for instance soda-lime glass, borosilicate glass, and the like), metal, polymer, ceramic, compound materials, carbon fiber materials or any other material or combination of materials which can be coated by a deposition process.

The term “masking” may include reducing and/or hindering a deposition of material on one or more regions of the substrate 10. The masking may be useful, for instance, in order to define the area to be coated. In some applications, only parts of the substrate 10 are coated and the parts not to be coated are covered by the mask.

FIG. 2 shows a schematic view of a carrier 200 for use in a vacuum system according to further embodiments described herein. The carrier 200 according to the present disclosure can be an electrostatic chuck (E-chuck) providing an electrostatic force for holding the substrate 10 and/or the mask 20 at the carrier 200. As an example, the carrier 200 includes an electrode arrangement 220 configured to provide an attracting force acting on at least one of the substrate 10 and the mask 20. The housing or enclosure, e.g. a recess, (not shown) can be provided adjacent to the electrode arrangement 220.

According to some embodiments, the carrier 100 includes a support surface 212, the electrode arrangement 220 having a plurality of electrodes 222 configured to provide an attracting force for holding at least one of the substrate 10 and the mask 20 at the support surface 212, and a controller. The controller can be included in the one or more electronic devices placed inside the housing having the gaseous atmosphere. The controller can be configured to apply one or more voltages to the electrode arrangement 220 to provide the attracting force (also referred to as “chucking force”).

The plurality of electrodes 222 of the electrode arrangement 220 can be embedded in the body 110 or can be provided, e.g., placed, on the body 110. According to some embodiments, which can be combined with other embodiments described herein, the body 110 is a dielectric body, such as a dielectric plate. The dielectric body can be fabricated from a dielectric material, preferably a high thermal conductivity dielectric material such as pyrolytic boron nitride, aluminum nitride, silicon nitride, alumina or an equivalent material, but may be made from such materials as polyimide. In some embodiments, the plurality of electrodes 222, such as a grid of fine metal strips, can be placed on the dielectric plate and covered with a thin dielectric layer.

According to some embodiments, which can be combined with other embodiments described herein, the carrier 200 includes one or more voltage sources configured to apply one or more voltages to the plurality of electrodes 222. The one or more voltage sources can be included in the one or more electronic devices placed in the sealed housing of the carrier 200 having the gaseous atmosphere. In some implementations, the one or more voltage sources are configured to ground at least some electrodes of the plurality of electrodes 222. As an example, the one or more voltage sources can be configured to apply a first voltage having a first polarity, a second voltage having a second polarity, and/or ground to the plurality of electrodes 222.

The electrode arrangement 220, and particularly the plurality of electrodes 222, is configured to provide the attracting force, such as a chucking force. The attracting force can be a force acting on the substrate 10 and/or the mask 20 at a certain relative distance between the plurality of electrodes 222 (or the support surface 112) and the substrate 10 and/or the mask 20. The attracting force can be an electrostatic force provided by the voltages applied to the plurality of electrodes 222. A magnitude of the attracting force may be determined by the voltage polarity and a voltage level. The attracting force can be changed by altering the voltage polarities and/or by altering the voltage level(s).

The substrate 10 is attracted by the attracting force provided by the carrier 200, which can be an E-chuck, towards the support surface 212 (e.g., in a direction 3, which can be a horizontal direction perpendicular to a vertical direction 1). The attracting force can be strong enough to hold the substrate 10 e.g. in a vertical position by frictional forces. In particular, the attracting force, can be configured to fix the substrate 10 essentially immoveably on the support surface 212. For example, to hold a 0.5 mm glass substrate in a vertical position using friction forces, an attracting pressure of about 50 to 100 N/m² (Pa) can be used, depending on the friction coefficient.

FIG. 3 shows a system 300 for vacuum processing according to embodiments described herein. The system 300, which can also be referred to as “vacuum system”, can be configured for depositing one or more layers, e.g. of an organic material, on the substrate 10.

The system 300 includes a vacuum chamber 302, the carrier 100 according to the embodiments described herein, and a transport arrangement 310 configured for transportation of the carrier 100 in the vacuum chamber 302. In some implementations, the system 300 includes one or more material deposition sources 380 in the vacuum chamber 302. The carrier 100 can be configured to hold the substrate 10 during a vacuum deposition process. The system 300 can be configured for evaporation of e.g. an organic material for the manufacture of OLED devices. In another example, the system 300 can be configured for CVD or PVD, such as sputter deposition.

In some implementations, the one or more material deposition sources 380 can be evaporation sources, particularly evaporation sources for depositing one or more organic materials on a substrate to form a layer of an OLED device. The carrier 100 for supporting the substrate 10, e.g. during a layer deposition process can be transported into and through the vacuum chamber 302, and in particular through a deposition area, along a transportation path, such as a linear transportation path.

The material can be emitted from the one or more material deposition sources 380 in an emission direction towards the deposition area in which the substrate 10 to be coated is located. For instance, the one or more material deposition sources 380 may provide a line source with a plurality of openings and/or nozzles which are arranged in at least one line along the length of the one or more material deposition sources 380. The material can be ejected through the plurality of openings and/or nozzles.

As indicated in FIG. 3, further chambers can be provided adjacent to the vacuum chamber 302. The vacuum chamber 302 can be separated from adjacent chambers by a valve having a valve housing 304 and a valve unit 306. After the carrier 100 with the substrate 10 thereon is inserted into the vacuum chamber 302 as indicated by the arrow, the valve unit 306 can be closed. The atmosphere in the vacuum chamber 302 can be individually controlled by generating a technical vacuum, for example with vacuum pumps connected to the vacuum chamber 302.

According to some embodiments, the carrier 100 and the substrate 10 are static or dynamic during deposition of the deposition material. According to some embodiments described herein, a dynamic deposition process can be provided, e.g., for the manufacture of OLED devices.

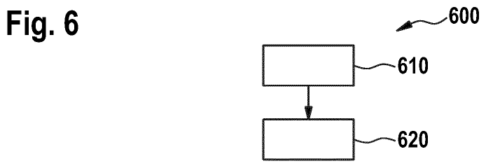

In some implementations, the system 300 can include one or more transportation paths extending through the vacuum chamber 302. The carrier 100 can be configured for transportation along the one or more transportation paths, for example, past the one or more material deposition sources 380. Although in FIG. 6 one transportation path is exemplarily indicated by the arrow, it is to be understood that the present disclosure is not limited thereto and that two or more transportation paths can be provided. As an example, at least two transportation paths can be arranged substantially parallel to each other for transportation of respective carriers. The one or more material deposition sources 380 can be arranged between the two transportation paths.

According to some embodiments, the transport arrangement 310 can be configured for at least one of contactless levitation of the carrier 100 and contactless transportation of the carrier 100 in the vacuum chamber, e.g., along the one or more transportation paths in the transport direction 2. The contactless levitation and/or transportation of the carrier 100 is beneficial in that no particles are generated during transportation, for example due to mechanical contact with guide rails. An improved purity and uniformity of the layers deposited on the substrate 10 can be provided, since particle generation is minimized when using the contactless levitation and/or transportation.

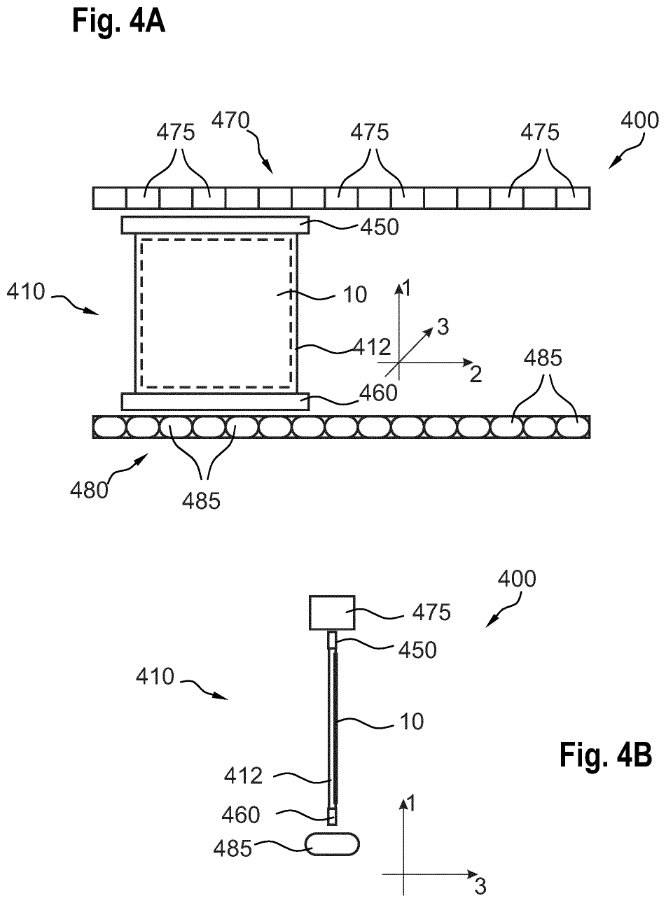

FIGS. 4A and B show schematic views of an exemplary transport arrangement for transporting a carrier 410 in a vacuum chamber according to embodiments described herein.

As illustrated in FIG. 4A, according to an embodiment, the transport arrangement 400 for contactless transportation of a carrier 410 is provided. The carrier 410 can include a first magnet unit configured to magnetically interact with a guiding structure 470 of the vacuum system for providing a magnetic levitation force for levitating the carrier 410. In particular, the carrier 410 can include a first magnet unit, such as a first passive magnetic unit 450. The transport arrangement 400 can include a guiding structure 470 extending in a carrier assembly transportation direction, such as the transport direction 2, which can be a horizontal direction. The guiding structure 470 can include a plurality of active magnetic units 475. The carrier 410 can be movable along the guiding structure 470. The first passive magnetic unit 450, e.g. a bar of ferromagnetic material, and the plurality of active magnetic units 475 of the guiding structure 470 can be configured for providing a first magnetic levitation force for levitating the carrier 410. The devices for levitating as described herein are devices for providing a contactless force to levitate e.g. the carrier 410.

According to some embodiments, which can be combined with other embodiments described herein, the transport arrangement 400 may be arranged in the vacuum chamber of the vacuum system. The vacuum chamber may be a vacuum deposition chamber.

In some implementations, the transport arrangement 400 may further include a drive structure 480. The drive structure 480 can include a plurality of further magnet units, such as further active magnetic units. The carrier 410 can include a second magnet unit configured to magnetically interact with the drive structure 480 of the vacuum system. In particular, the carrier 410 can include the second magnet unit, such as a second passive magnetic unit 460, e.g. a bar of ferromagnetic material to interact with the further active magnetic units 485 of the drive structure 480.

FIG. 4B shows another side view of the transport arrangement 400. In FIG. 4B, an active magnetic unit of the plurality of active magnetic units 475 is shown. The active magnetic unit provides a magnetic force interacting with the first passive magnetic unit 450 of the carrier 410. For example, the first passive magnetic unit 450 can be a rod of a ferromagnetic material. A rod can be a portion of the carrier 410 that is connected to a support structure 412. The support structure 412 can be provided by the body of the carrier 410. The rod or the first passive magnetic unit, respectively, may also be integrally formed with the support structure 412 for supporting the substrate 10. The carrier 410 can further include the second passive magnetic unit 460, for example a further rod. The further rod can be connected to the carrier 410. The rod or the second passive magnetic unit, respectively, may also be integrally formed with the support structure 412.

The terminology of a “passive” magnetic unit is used herein to distinguish from the notion of an “active” magnetic unit. A passive magnetic unit may refer to an element with magnetic properties, which are not subject to active control or adjustment, at least not during operation of the transport arrangement 400. For example, the magnetic properties of a passive magnetic unit, e.g. the rod or the further rod of the carrier, are not subject to active control during movement of the carrier through the vacuum chamber or vacuum system in general. According to some embodiments, which can be combined with other embodiments described herein, a controller of the transport arrangement 400 is not configured to control a passive magnetic unit. A passive magnetic unit may be adapted for generating a magnetic field, e.g. a static magnetic field. A passive magnetic unit may not be configured for generating an adjustable magnetic field. A passive magnetic unit may be a magnetic material, such as a ferromagnetic material, a permanent magnet or may have permanent magnetic properties.

As compared to a passive magnetic unit, an active magnetic unit offers more flexibility and precision in light of the adjustability and controllability of the magnetic field generated by the active magnetic unit. According to embodiments described herein, the magnetic field generated by an active magnetic unit may be controlled to provide for an alignment of the carrier 410. For example, by controlling the adjustable magnetic field, a magnetic levitation force acting on the carrier 410 may be controlled with high accuracy, thus allowing for a contactless alignment of the carrier and, thus, a substrate, by the active magnetic unit.

According to embodiments described herein, the plurality of active magnetic units 475 provides for a magnetic force on the first passive magnetic unit 450 and thus, the carrier 410. The plurality of active magnetic units 475 levitates the carrier 410. The further active magnetic units 485 can drive the carrier 410 within the vacuum chamber, for example along the transport direction 2. The plurality of further active magnetic units 485 form the drive structure for moving the carrier 410 in the transport direction 2 while being levitated by the plurality of active magnetic units 475 located above the carrier 410. The further active magnetic units 485 can interact with the second passive magnetic unit 460 to provide a force along the transport direction 2. For example, the second passive magnetic unit 460 can include a plurality of permanent magnets arranged with an alternating polarity. The resulting magnetic fields of the second passive magnetic unit 460 can interact with the plurality of further active magnetic units 485 to move the carrier 410 while being levitated.

In order to levitate the carrier 410 with the plurality of active magnetic units 475 and/or to move the carrier 410 with the plurality of further active magnetic units 485, the active magnetic units can be controlled to provide adjustable magnetic fields. The adjustable magnetic field may be a static or a dynamic magnetic field. According to embodiments, which can be combined with other embodiments described herein, an active magnetic unit is configured for generating a magnetic field for providing a magnetic levitation force extending along a vertical direction 1. According to other embodiments, which can be combined with further embodiments described herein, an active magnetic unit may be configured for providing a magnetic force extending along a transversal direction. An active magnetic unit, as described herein, may be or include an element selected from the group consisting of an electromagnetic device, a solenoid, a coil, a superconducting magnet, or any combination thereof.

Embodiments described herein relate to contactless levitation, transportation and/or alignment of a carrier, a substrate and/or a mask. The disclosure refers to a carrier, which may include one or more elements of the group consisting of a carrier supporting a substrate, a carrier without a substrate, a substrate, or a substrate supported by a support. The term “contactless” as used throughout the present disclosure can be understood in the sense that a weight of, e.g. the carrier and the substrate, is not held by a mechanical contact or mechanical forces, but is held by a magnetic force. Specifically, the carrier is held in a levitating or floating state using magnetic forces instead of mechanical forces. As an example, the transport arrangement described herein may have no mechanical devices, such as a mechanical rail, supporting the weight of the carrier. In some implementations, there can be no mechanical contact between the carrier and the rest of the apparatus at all during levitation, and for example movement, of the carrier in the vacuum system.

According to embodiments of the present disclosure, levitating or levitation refers to a state of a unit, wherein the unit floats without mechanical contact or support. Further, moving a unit refers to providing a driving force, e.g. a force in a direction different to a levitation force, wherein the unit is moved from one position to another, different position.

For example, a unit such as a carrier can be levitated, i.e. by a force counteracting gravity, and can be moved in a direction different to a direction parallel to gravity while being levitated.

The contactless levitation, transportation and/or alignment of the carrier according to embodiments described herein is beneficial in that no particles are generated due to a mechanical contact between the carrier and sections of the transport arrangement 400, such as mechanical rails, during the transport or alignment of the carrier. Accordingly, embodiments described herein provide for an improved purity and uniformity of the layers deposited on the substrate, in particular since particle generation is minimized when using the contactless levitation, transportation and/or alignment.

A further advantage, as compared to mechanical devices for guiding the carrier, is that embodiments described herein do not suffer from friction affecting the linearity and/or precision of the movement of the carrier. The contactless transportation of the carrier allows for a frictionless movement of the carrier, wherein an alignment of the carrier assembly relative to a mask can be controlled and maintained with high precision. Yet further, the levitation allows for fast acceleration or deceleration of the carrier speed and/or fine adjustment of the carrier speed.

Further, the material of mechanical rails typically suffers from deformations, which may be caused by evacuation of a chamber, by temperature, usage, wear, or the like. Such deformations affect the position of the carrier, and hence affect the quality of the deposited layers. In contrast, embodiments described herein allow for a compensation of potential deformations present in e.g. the guiding structure described herein. In view of the contactless manner in which the carrier is levitated and transported, embodiments described herein allow for a contactless alignment of the carrier. Accordingly, an improved and/or more efficient alignment of the substrate relative to the mask can be provided.

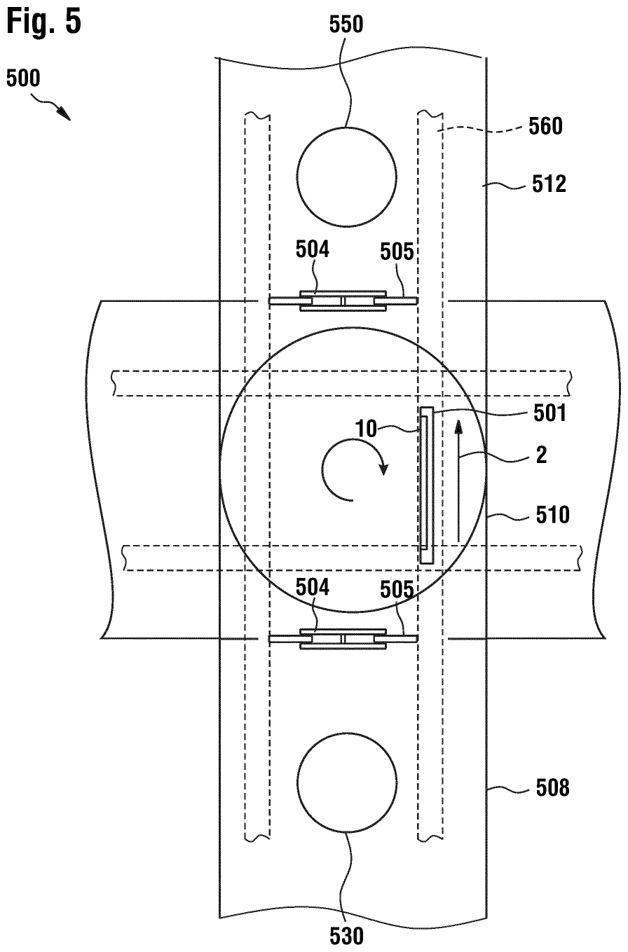

FIG. 5 shows a schematic view of a system 500 for vacuum processing of a substrate 10 according to further embodiments described herein.

The system 500 includes two or more processing regions and a transport arrangement 560 configured for sequentially transporting a carrier 501 supporting a substrate 10 and optionally a mask to the two or more processing regions. As an example, the transport arrangement 560 can be configured for transporting the carrier 501 along the transport direction 2 through the two or more processing regions for substrate processing. In other words, the same carrier is used for transportation of the substrate 10 through multiple processing regions. In particular, the substrate 10 is not removed from the carrier 501 between substrate processing in a processing region and substrate processing a subsequent processing region, i.e., the substrate stays on the same carrier for two or more substrate processing procedures. According to some embodiments, the carrier 501 can be configured according to the embodiments described herein. Optionally or alternatively, the transport arrangement 560 can be configured as described with respect to, for example, FIGS. 4A and B.

As exemplarily illustrated in FIG. 5, the two or more processing regions can include a first deposition region 508 and a second deposition region 512. Optionally, a transfer region 510 can be provided between the first deposition region 508 and the second deposition region 512. The plurality of regions, such as the two or more processing regions and the transfer region, can be provided in one vacuum chamber. Alternatively, the plurality of regions can be provided in different vacuum chambers connected to each other.

As an example, each vacuum chamber can provide one region. Specifically, a first vacuum chamber can provide the first deposition region 508, a second vacuum chamber can provide the transfer region 510, and a third vacuum chamber can provide the second deposition region 512. In some implementations, the first vacuum chamber and the third vacuum chamber can be referred to as “deposition chambers”. The second vacuum chamber can be referred to as “processing chamber”. Further vacuum chambers or regions can be provided adjacent to the regions shown in the example of FIG. 5.

The vacuum chambers or regions can be separated from adjacent regions by a valve having a valve housing 504 and a valve unit 505. After the carrier 501 with the substrate 10 thereon is inserted into a region, such as the second deposition region 512, the valve unit 505 can be closed. The atmosphere in the regions can be individually controlled by generating a technical vacuum, for example, with vacuum pumps connected to the regions and/or by inserting one or more process gases, for example, in the first deposition region 508 and/or the second deposition region 512. A transportation path, such as a linear transportation path, can be provided in order to transport the carrier 501, having the substrate 10 thereon, into, through and out of the regions. The transportation path can extend at least in part through the two or more processing regions, such as the first deposition region 508 and the second deposition region 512, and optionally through the transfer region 510.

The system 500 can include the transfer region 510. In some embodiments, the transfer region 510 can be omitted. The transfer region 510 can be provided by a rotation module, a transit module, or a combination thereof. FIG. 5 illustrates a combination of a rotation module and a transit module. In the rotation module, the track arrangement and the carrier(s) arranged thereon can be rotated around a rotational axis, such as a vertical rotation axis. As an example, the carrier(s) can be transferred from the left side of the system 500 to the right side of the system 500, or vice versa. The transit module can include crossing tracks such that carrier(s) can be transferred through the transit module in different directions, e.g., directions perpendicular to each other.

Within the deposition regions, such as the first deposition region 508 and the second deposition region 512, one or more deposition sources can be provided. As an example, a first deposition source 530 can be provided in the first deposition region 508. A second deposition source 550 can be provided in the second deposition region 512. The one or more deposition sources can be evaporation sources configured for deposition of one or more organic layers on the substrate 10 to form an organic layer stack for an OLED device.

FIG. 6 shows a flow chart of a method 600 for vacuum processing of a substrate according to embodiments described herein. The method can utilize the carriers and the systems according to the present disclosure.

The method 600 includes, in block 610, a supporting of at least one of the substrate and a mask on a carrier in a vacuum chamber, wherein the carrier includes a housing or space accommodating one or more electronic devices, and, in block 620, a containing or maintaining of a gaseous environment inside the housing or space during the vacuum processing of the substrate in the vacuum chamber. In some implementations, the method 600 further includes contactlessly holding and/or transporting the carrier 100 in the vacuum chamber. For example, magnetic and/or electromagnetic forces can be used to hold the carrier 100 in a suspended or levitating state. In particular, the carrier 100 can be held from above using magnetic and/or electromagnetic forces. The housing can be an enclosure or a recess, which can be sealed.

According to some embodiments, the method 600 further includes a measuring of a gas pressure inside the housing using at least one electronic device of the one or more electronic devices, and wirelessly transmitting the gas pressure to a monitoring device remote from the carrier. As an example, if a pressure drop is detected in the sealed housing of the carrier while the carrier is in the vacuum environment, it can be concluded that gas from the housing leaks into the vacuum environment. Further embodiments, may measure leakage current of the E-chuck, failure of the battery, and/or de-chucking of the substrate, e.g. a glass substrate.

According to embodiments described herein, the method for vacuum processing can be conducted using computer programs, software, computer software products and the interrelated controllers, which can have a CPU, a memory, a user interface, and input and output devices being in communication with the corresponding components of the apparatus for processing a large area substrate.

The carrier of the present disclosure has a housing or space accommodating one or more electronic devices, such as control devices used for controlling an operation and/or a movement of the carrier. The housing contains a gaseous environment even if the carrier is located inside the vacuum chamber, i.e., in a vacuum environment. The carrier of the present disclosure can be an autonomous entity that is not mechanically connected e.g. via wires or cables to the surroundings of the carrier. An improved purity and uniformity of the layers deposited on the substrate can be achieved, since particle generation during a movement of the carrier is minimized. Further, the vacuum inside the vacuum chamber is not compromised, because the housing having the gaseous environment is sealed. Moreover, the vacuum inside the vacuum chamber can even be improved, because there is no need to establish vacuum conditions in a challenging region, i.e., the region having the one or more electronic components.

While the foregoing is directed to embodiments of the disclosure, other and further embodiments of the disclosure may be devised without departing from the basic scope thereof, and the scope thereof is determined by the claims that follow.

1. A carrier for use in a vacuum system, comprising:
a housing configured to accommodate one or more electronic devices and contain a gaseous environment during the use of the carrier in the vacuum system,
wherein the carrier is configured to hold at least one of a substrate and a mask used during vacuum processing.

2. The carrier of claim 1, wherein the housing includes an opening and a closure element configured to seal the opening essentially vacuum-tight.

3. The carrier of claim 2, further including a fastening arrangement configured for fastening the closure element to seal the housing.

4. The carrier of claim 1, wherein the one or more electronic devices are selected from the group consisting of a first control device for controlling a movement of the carrier, a second control device for controlling one or more operation parameters of the carrier, an alignment control device, a wireless transmitting device, a pressure sensor, and a power source.

5. The carrier of claim 4, wherein the pressure sensor is configured to measure a gas pressure inside the housing.

6. The carrier of claim 1, wherein the carrier is configured for at least one of contactless levitation and contactless transportation in the vacuum system.

7. The carrier of claim 1, further including a first magnet unit configured to magnetically interact with a guiding structure of the vacuum system for providing a magnetic levitation force for levitating the carrier.

8. The carrier of claim 1, further including a second magnet unit configured to magnetically interact with a drive structure of the vacuum system for moving the carrier in a transport direction.

9. The carrier of claim 1, further including an electrode arrangement configured to provide an attracting force acting on at least one of the substrate and the mask.

10. The carrier of claim 9, wherein the housing is provided adjacent to the electrode arrangement.

11. A carrier for use in a vacuum system, comprising:
a support structure having a receiving surface for a mask or a substrate thereon and a sealable recess therein to accommodate one or more electronic devices.

12. The carrier of claim 11, wherein the sealable recess includes an opening and a closure element configured to seal the opening.

13. The carrier of claim 12, further comprising a fastening arrangement configured for fastening the closure element to seal the sealable recess.

14. The carrier of claim 11, wherein the one or more electronic devices are selected from the group consisting of a first control device for controlling a movement of the carrier, a second control device for controlling one or more operation parameters of the carrier, an alignment control device, a wireless transmitting device, a pressure sensor, and a power source.

15. The carrier of claim 14, wherein the pressure sensor is configured to measure a gas pressure inside the sealable recess.

16. The carrier of claim 11, wherein the carrier is configured for at least one of contactless levitation and contactless transportation in a vacuum system.

17. The carrier of claim 11, further including a first magnet unit of a magnetic levitation and transportation system to provided forces for levitating the carrier.

18. The carrier of claim 11, further comprising a second magnet unit of a magnetic levitation and transportation system to provide forces for transporting the carrier.

19. The carrier of claim 11, wherein the receiving surface comprises an electrode arrangement configured to provide an attracting force acting on at least one of the substrate and the mask.

20. The carrier of claim 19, wherein the sealable recess is provided adjacent to the electrode arrangement.

21. A system for vacuum processing, comprising:
a vacuum chamber;
a carrier for use in a vacuum system, the carrier comprising:
a housing configured to accommodate one or more electronic devices and contain a gaseous environment during the use of the carrier in the vacuum system,
wherein the carrier is configured to hold at least one of a substrate and a mask used during vacuum processing; and
a transport arrangement configured for transportation of the carrier in the vacuum chamber.

22. The system of claim 21, wherein the transport arrangement is configured for at least one of contactless levitation of the carrier and contactless transportation of the carrier in the vacuum chamber.

23. A method for vacuum processing of a substrate, comprising:
supporting at least one of the substrate and a mask on a carrier in a vacuum chamber, wherein the carrier includes a housing accommodating one or more electronic devices, and
containing a gaseous environment inside the housing during the vacuum processing of the substrate in the vacuum chamber.

24. The method of claim 23, further including:
measuring a gas pressure inside the housing using at least one electronic device of the one or more electronic devices; and
wirelessly transmitting the gas pressure to a monitoring device remote from the carrier.

25. A method for vacuum processing of a substrate, comprising:
supporting at least one of the substrate and a mask on a carrier in a vacuum chamber, wherein the carrier includes a sealable recess accommodating one or more electronic devices and
maintaining a gaseous environment inside the sealable recess during the vacuum processing of the substrate in the vacuum chamber.

26. The method of claim 25, further including:
measuring a gas pressure inside the sealable recess using at least one electronic device of the one or more electronic devices; and
wirelessly transmitting the gas pressure to a monitoring device remote from the carrier.

27. The method of claim 23, further including:
contactlessly holding the carrier in the vacuum chamber.
